(19) United States
(12) Patent Application Publication
(10) Pub. No.: US 2026/0155333 A1
(43) Pub. Date: Jun. 4, 2026

(54) SYSTEMS AND METHODS FOR CONTROLLING A PULSE WIDTH OF A SQUARE PULSE WAVEFORM

(71) Applicant: Lam Research Corporation, Fremont, CA (US)

(72) Inventors: Alexei M. Marakhtanov, Albany, CA (US); Lin Zhao, Fremont, CA (US); Kenneth Lucchesi, Newark, CA (US); Bongseong Kim, San Ramon, CA (US); Leonid Belau, Pleasanton, CA (US); Eric A. Hudson, Berkeley, CA (US); John P. Holland, San Jose, CA (US)

(21) Appl. No.: 19/122,721

(22) PCT Filed: Oct. 10, 2023
(86) PCT No.: PCT/US2023/076510

§ 371 Date: Apr. 18, 2025

Related U.S. Application Data
(60) Provisional application No. 63/419,291, filed on Oct. 25, 2022.

(51) Int. Cl. H01J 37/32; H03K 7/08

(52) U.S. Cl. CPC H01J 37/32146; H01J 37/32183

(57) ABSTRACT

Systems and methods for controlling a pulse width of a square pulse waveform are described. One of the methods includes generating the square pulse waveform having a plurality of states. Each of the plurality of states includes a series of square pulses. The method includes modifying the pulse width of each of the plurality of states to modify a rate of processing a substrate.

### FIELD

The present embodiments relate to systems and methods for controlling a pulse width of a square pulse waveform.

### BACKGROUND

In a plasma tool, a radio frequency (RF) generator is provided to generate a sinusoidal RF signal. The plasma tool has a match coupled to the RF generator for receiving the sinusoidal RF signal. The match, in response to receiving the sinusoidal RF signal from the RF generator, outputs a sinusoidal RF signal towards a plasma chamber of the plasma tool. A semiconductor wafer placed within the plasma chamber is processed by plasma generated when the sinusoidal RF signal is received from the match. However, the sinusoidal RF signal generated by the RF generator does not facilitate achieving a variety of processes for fabrication of the semiconductor wafer.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Embodiments of the disclosure provide systems, apparatus, methods and computer programs for controlling a pulse width of a square pulse waveform. It should be appreciated that the present embodiments can be implemented in numerous ways, e.g., a process, an apparatus, a system, a device, or a method on a computer readable medium. Several embodiments are described below.

In an embodiment, a method for adjusting a pulse width of a square pulse waveform is described. The method includes generating the square pulse waveform having a plurality of states and a second plurality of states. Each of the plurality of states includes a series of square pulses. The method includes modifying the pulse width of each of the plurality of states to modify a rate of processing a substrate.

In one embodiment, a controller for adjusting a pulse width of a square pulse waveform is described. The controller includes a processor that controls a pulse generator to generate the square pulse waveform having a plurality of states. Each of the plurality of states includes a series of square pulses. The processor controls the pulse generator to modify the pulse width of each of the plurality of states to modify a rate of processing a substrate. The controller includes a memory device coupled to the processor.

In an embodiment, a plasma system includes a low frequency (LF) radio frequency (RF) pulse generator, a high frequency (HF) RF signal generator, an HF filter coupled to the LF RF pulse generator, an impedance matching circuit coupled to the HF RF signal generator, and a plasma chamber coupled to the HF filter and the impedance matching circuit. The plasma system further includes a controller coupled to the LF RF pulse generator and the HF RF signal generator. The controller controls the LF RF pulse generator to generate a square pulse waveform having a plurality of states. Each of the plurality of states includes a series of square pulses. The controller controls the LF RF pulse generator to modify a pulse width of each of the plurality of states to modify a rate of processing a substrate.

Some advantages of the herein described systems and methods include controlling the pulse width of the square pulse waveform for achieving uniformity across features of a substrate. The pulse width is controlled by increasing or decreasing a number of pulses of the square pulse waveform. In addition, by controlling the pulse width, a rate of processing the substrate is controlled. Also, by controlling the pulse width, selectivity associated with processing the substrate is controlled. By controlling the pulse width, a growth rate of a bow of the substrate is controlled.

Additional advantages of the herein described systems and methods include achieving a faster rate of processing the substrate compared to that achieved using a sinusoidal RF signal. The square pulse waveform achieves a power setpoint at a rate faster than a rate of achieving the power setpoint using the sinusoidal RF signal. By achieving the faster rate, the substrate can be processed quicker compared to that using the sinusoidal RF signal.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1A is an embodiment of a graph to illustrate a square pulse waveform having a pulse width.

FIG. 1B is a diagram of an embodiment of a graph to illustrate multiple states, S1 and S0, of a square pulse waveform in which the state S0 has multiple pulses.

FIG. 2 is an embodiment of a graph to illustrate a change in a pulse width.

FIG. 3 is an embodiment of a graph to illustrate a change in a pulse width

FIG. 4 is an embodiment of a graph to illustrate a change in a pulse width.

FIG. 5A is a diagram of an embodiment of a system to illustrate use of a high frequency radio frequency (HF RF) signal generator that generates an RF signal to be used in conjunction with a low frequency (LF) RF pulse generator.

FIG. 5B is a diagram of an embodiment of a system to illustrate use of the HF RF signal generator with the LF RF pulse generator.

FIG. 6 is an embodiment of system that includes a processor and the LF RF pulse generator.

FIG. 7A-1 is an embodiment of a graph to illustrate a continuous waveform of the RF signal generated by the HF RF signal generator.

FIG. 7A-2 is an embodiment of a graph to illustrate an envelope and a phase of a square pulse waveform.

FIG. 7B-1 is an embodiment of a graph to illustrate an envelope of a parameter of an RF signal that is generated by the HF RF signal generator of FIG. 5B.

FIG. 7B-2 is an embodiment of a graph to illustrate a change in a phase of an envelope of a square pulse waveform from a phase 1 to a phase 2.

FIG. 7B-3 is an embodiment of a graph to illustrate a change in the phase of the envelope of the square pulse waveform from the phase 2 to a phase 3.

FIG. 7B-4 is an embodiment of a graph to illustrate a change in the phase of the envelope of the square pulse waveform from the phase 3 to a phase 4.

FIG. 7B-5 is an embodiment of a graph to illustrate a change in the phase of the envelope of the square pulse waveform from the phase 4 to a phase 5.

FIG. 8 is an embodiment of a graph to illustrate that an etch rate (ER) of etching a substrate changes with a change in a pulse width of a square pulse waveform.

FIG. 9 is an embodiment of a graph to illustrate that selectivity of etching a layer of the substrate changes with a change in a pulse width of a square pulse waveform.

FIG. 10 is an embodiment of a graph to illustrate that a bow growth rate of a wafer bow of the substrate changes with a change in a pulse width of a square pulse waveform.

FIG. 11 is a diagram to illustrate that with a change in a pulse width of a square pulse waveform, there is a change in a chemical composition of plasma.

FIG. 12 is an embodiment of a graph to illustrate that a rate of transition between two states of an RF signal is greater than a rate of transition between two states of a square pulse waveform.

### DETAILED DESCRIPTION

The following embodiments describe systems and methods for controlling a pulse width of a square pulse waveform. It will be apparent that the present embodiments may be practiced without some or all of these specific details. In other instances, well known operations have not been described in detail in order not to unnecessarily obscure the present embodiments.

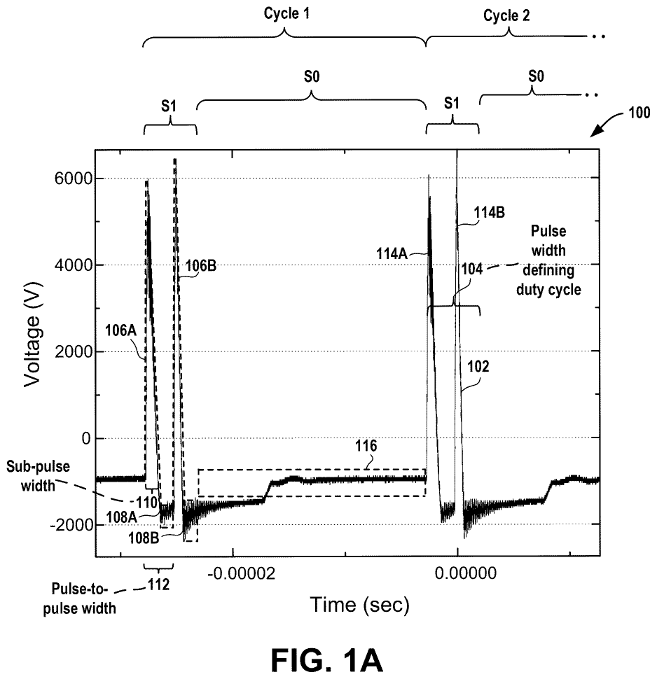

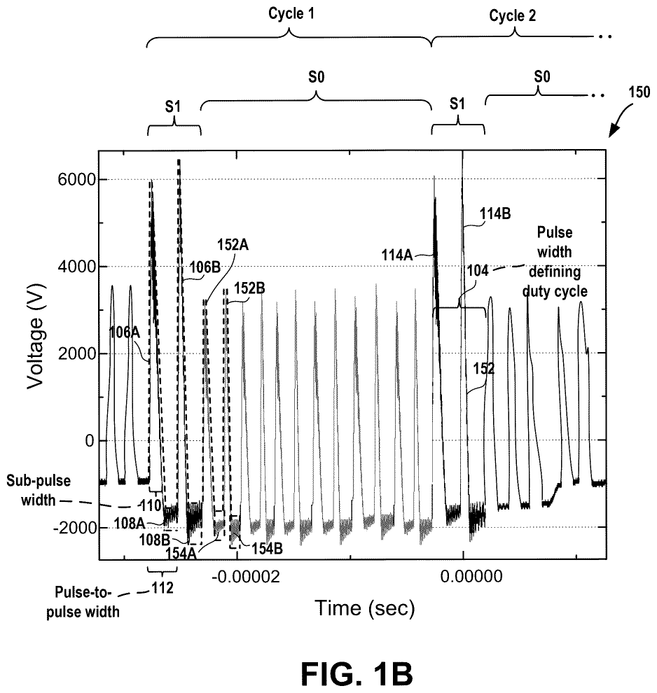

FIG. 1A is an embodiment of a graph 100 to illustrate a square pulse waveform 102 having a pulse width 104. The graph 100 plots a parameter, such as power or voltage (V), of the square pulse waveform 102 on a y-axis and time t on an x-axis. The time t is measured in seconds.

Also, the square pulse waveform 102 has a sub-pulse width 110 and a pulse-to-pulse width 112. As an example, the sub-pulse width 110 is a time interval, such as an average time period or a median time period, of occurrence of each pulse of the square pulse waveform 202. Also, is an example, the pulse-to-pulse width 112 is a time interval, such as an average time period or a median time period, between two consecutive pulses of the square pulse waveform 202 during a cycle of a clock signal.

An example of a square pulse waveform, described herein, is a non-sinusoidal radio frequency (RF) signal having one or more pulses followed by radio frequency (RF) voltage oscillations during a high state and no pulses during a low state. To illustrate, during the high state, such as a state S1 or a first state, of the square pulse waveform, the square pulse waveform has a series of a pre-determined number of pulses, with each of the pulses followed by respective RF voltage oscillations. In the illustration, during the high state of the square pulse waveform, the square pulse waveform achieves a series of high amplitudes of the parameter for a pre-determined number of times, and each of the high amplitudes of the series is immediately followed by RF voltage oscillations. In the illustration, the high amplitudes include a maximum amplitude of the square pulse waveform. Also, in the illustration, an envelope, such as an amplitude, of the RF voltage oscillations is substantially less than the high amplitudes. In the illustration, the high amplitudes are greater than the amplitude of the RF voltage oscillations by at least 100%. Also, in the illustration, each pulse of the square pulse waveform is of a triangular shape and is not sinusoidal. In the illustration, the square pulse waveform derives its name because a substantially square-shaped envelope can surround each pulse of the square pulse waveform. To further illustrate, the square pulse waveform 102 has a series of pulses 106A and 106B, the pulse 106A is immediately followed by RF voltage oscillations 108A and the pulse 106B is immediately followed by RF voltage oscillations 108B.

Continuing with the illustration, the RF voltage oscillations diminish over time from a higher amplitude to a lower amplitude. Further, in the illustration, the lower amplitude is output as a diminished amplitude. In the illustration, during the low state, such as a state S0 or a second state, of the square pulse waveform, there is not a single occurrence of a pulse. Also, in the illustration, in the low state, the square pulse waveform has the diminished amplitude or an amplitude less than the diminished amplitude. Moreover in the illustration, the amplitude of the state S0 of the square pulse waveform falls within a pre-determined range and the amplitude of RF voltage oscillations that precede the state S0 is outside the pre-determined range.

The square pulse waveform is in comparison to a sinusoidal RF signal in which, during each state of the sinusoidal RF signal, amplitudes of the sinusoidal RF signal are within a pre-determined range. For example, an amplitude of a portion of a state of the sinusoidal RF signal is not greater than an amplitude of remaining portion of the state of the sinusoidal RF signal by at least 100%. An example of an amplitude, as used herein, is an envelope, such as a zero-to-peak amplitude or a peak-to-peak amplitude.

An example of a pulse width of a square pulse waveform is a time interval, such as a statistical time period, of each occurrence of one or more pulses, such as the series of pulses, of the square pulse waveform and one or more RF voltage oscillations associated with the one or more pulses during the state S1 of the square pulse waveform. In the example, each of the one or more pulses precedes a respective one of the RF voltage oscillations. To illustrate, the square pulse waveform 102 has the pulse width 104, which includes time intervals of occurrences of the pulses 106A and 106B and occurrences of the RF voltage oscillations 108A and 108B.

An example of a pulse-to-pulse width of a square pulse waveform is a time interval, such as a statistical time period, between two consecutive pulses of a state of the square pulse waveform. To illustrate, the pulse-to-pulse width is a time interval between a time at which a first pulse of the square pulse waveform is generated and a time at which a second pulse of the square pulse waveform is generated. In the illustration, the second pulse is consecutive to the first pulse and there are no other pulses between the first and second pulses. Further in the illustration, both the first and second pulses are of the same state S1 of the square pulse waveform. To further illustrate, the pulse-to-pulse width is a time interval between a time at which the first pulse starts transitioning from the state S0 to the state S1 and a time at which the second pulse starts transitioning from RF voltage oscillations to the state S1. In the further illustration, the RF voltage oscillations immediately follow the first pulse and precede the second pulse. As another further illustration, the pulse-to-pulse width is the time interval between a time at which the first pulse starts transitioning from a first plurality of RF voltage oscillations to the high amplitudes of the state S1 of the square pulse waveform and the time at which the second pulse starts transitioning from a second plurality of RF voltage oscillations to the high amplitudes of the state SI of the square pulse waveform. In the further illustration, the first plurality of RF voltage oscillations precede the first pulse, and the second plurality of RF voltage oscillations immediately follow the first pulse and precedes the second pulse. An example of a statistical value is an average value or a median value. To illustrate, the statistical time period is an average time interval or a median time interval.

An example of a sub-pulse width is a time interval, such as a statistical time period, for which each pulse of the square pulse waveform is generated. To illustrate, the sub-pulse width is a time interval between a time at which a pulse starts transitioning from the state S0 to the state S1 and a time at which the pulse ends transitioning from the state SI to a plurality of RF voltage oscillations. In the illustration, the plurality of RF voltage oscillations immediately follow the pulse. As another illustration, the sub-pulse width is a time interval between a time at which a pulse starts transitioning from an amplitude of the parameter of a first plurality of RF voltage oscillations to the high amplitudes of the state S1 and a time at which the pulse ends transitioning from the high amplitudes of the state S1 to a second plurality of RF voltage oscillations. In the illustration, the first plurality of RF voltage oscillations precede the pulse and the second plurality of RF voltage oscillations immediately follow the pulse.

The states S1 and S0 of the square pulse waveform repeat during each cycle of the clock signal. For example, a first instance of the state S1 and a first instance of the state S0 occurs during a first cycle of the clock signal, and a second instance of the state S1 and a second instance of the state S0 occurs during a second cycle of the clock signal. The second cycle, in the example, is consecutive to the first cycle. To illustrate, the pulses 106A and 106B occur during a cycle 1 of the clock signal and pulses 114A and 114B of the square pulse waveform 102 occur during a cycle 2 of the clock signal.

It should be noted that a square pulse waveform, described herein, has a rate of transition from the state S0 to the state SI that is greater than a rate of transition of the sinusoidal RF signal from a state S0 to a state S1. For example, the square pulse waveform 102 lacks a concave-shaped transition from the state S0 to the state S1. In the example, the concave-shaped transition has a concave envelope, such as a concave amplitude or an arc-shaped envelope. To illustrate, a transition of the square pulse waveform 102 from the state S0 to the state SI has an infinite slope or a substantially infinite slope. To further illustrate, the pulse 106A achieves an amplitude of the state SI at the same time or substantially at the same time at which the pulse 106A has an amplitude of the state S0. As another illustration, a transition of the pulse 106A from the state S0 to the state S1 has a straight slope. This is in comparison to a curved slope, such as a concave slope, of a transition of the sinusoidal RF signal from the state S0 to the state S1. As another example, the sinusoidal RF signal has a large number of RF cycles, such as 8-12 cycles, to ramp up from the state S0 to the state S1 to achieve a power setpoint and it takes about 20 microseconds to achieve the power setpoint. In the example, the sinusoidal RF signal has a large number of RF cycles, such as greater than 20 RF cycles, to ramp down from the state S1 to the state S0. In the example, the large number of RF cycles at either the ramp up or the ramp down does not facilitate certain operations of processing a substrate.

Similarly, the square pulse waveform has a rate of transition from the state S1 to the state S0 that is greater than a rate of transition of the sinusoidal RF signal the state S1 to the state S0. For example, the square pulse waveform 102 lacks a transition from the state SI to the state S0. To illustrate, a transition of the square pulse waveform 102 from the state S1 to the state S0 has an infinite slope or a substantially infinite slope. To further illustrate, the pulse 106B achieves an amplitude of the state SI at the same time or substantially at the same time at which the pulse 106B has an amplitude of the state S0. As another illustration, a transition of the pulse 106B from the state S1 to the state S0 has a straight slope. This is in comparison to a curved slope, such as a concave slope, of a transition of the sinusoidal RF signal from the state S1 to the state S0.

The greater rates of transitions facilitates achieving a power setpoint, received within a recipe signal, described below, faster than achieving the power setpoint by generated the sinusoidal RF signal. An example of the power setpoint includes a supply power setpoint or a delivered power setpoint. To illustrate, supplied power is power supplied by an RF generator, such as a low frequency (LF) RF pulse generator, described below, or a high frequency (HF) RF signal generator, also described below. An example of LF is 400 kilohertz (kHz) and of HF is 27 megahertz (MHz) or 60 MHz. Another example of LF is 2 MHz and of HF is 27 MHz or 60 MHz. Yet another example of LF is a frequency from and including 1 kHz to 800 kHz. To illustrate, LF is a frequency of 10 kHz, or 100 kHz, or 400 kHz, or 800 kHz. Delivered power is a difference between the supplied power and reflected power. The reflected power is power reflected from a plasma chamber towards the RF generator.

It should be noted that the state S0 of the sinusoidal RF signal includes a series of sine waves and the state S1 of the sinusoidal RF signal includes a series of sine waves. Further, an amplitude of the state S1 of the sinusoidal RF signal is greater than an amplitude of the state S0 of the sinusoidal RF signal. For example, the amplitude of the state S1 of the sinusoidal RF signal falls outside a pre-set range of the amplitude of the state S0 of the sinusoidal RF signal.

In an embodiment, the terms RF voltage oscillations and RF oscillations are used herein interchangeably. For example, RF oscillations is sometimes referred to herein as RF voltage oscillations.

In one embodiment, RF voltage oscillations, when corrected, such as removed, becomes flat. For example, the RF voltage oscillations is represented using a horizontal line. To illustrate, the RF voltage oscillations is sometimes referred to herein as a flat portion.

FIG. 1B is a diagram of an embodiment of a graph 150 to illustrate the states S1 and S0 of a square pulse waveform 152 in which the state S0 has multiple pulses. The graph 150 plots 100 plots the parameter of the square pulse waveform 152 on a y-axis and the time t on an x-axis.

The graph 152 is similar to the graph 100 (FIG. 1A) except in the graph 100, during the state S0, the square pulse waveform 152 has multiple pulses, such as a pulse 152A and a pulse 152B, during the state S0 of the square pulse waveform 152. Moreover, similar to the state S1, each pulse during the state S0 of the square pulse waveform 152 is followed by respective RF oscillations, such as RF oscillations 154A and RF oscillations 154B. For example, the pulse 152A is immediately followed by the RF oscillations 154A and the pulse 152B is immediately followed by the RF oscillations 154B. The state S0 of the square pulse waveform 152 occurs during each cycle of the clock signal.

Similar to the state S1 of the square pulse waveform 152, the state S0 has a pulse-to-pulse width and has a sub-pulse width. For example, the pulse-to-pulse width during the state S0 is a time interval between starts of two consecutive pulses, such as the pulses 152A and 152B, of the square pulse waveform 152. In the example, the sub-pulse width during the state S0 is a time interval spanning a width of each pulse, such as the pulse 152A or 152B, of the square pulse waveform 152.

Amplitudes, such as peak-to-peak amplitudes or zero-to-peak amplitudes, of the state S0 of the square pulse waveform 152 are less than the high amplitudes of the state S1 of the square pulse waveform 152. For example, the amplitudes of the state S0 of the square pulse waveform 152 are less than the amplitudes of the state S1 of the square pulse waveform 152 by at least 10%.

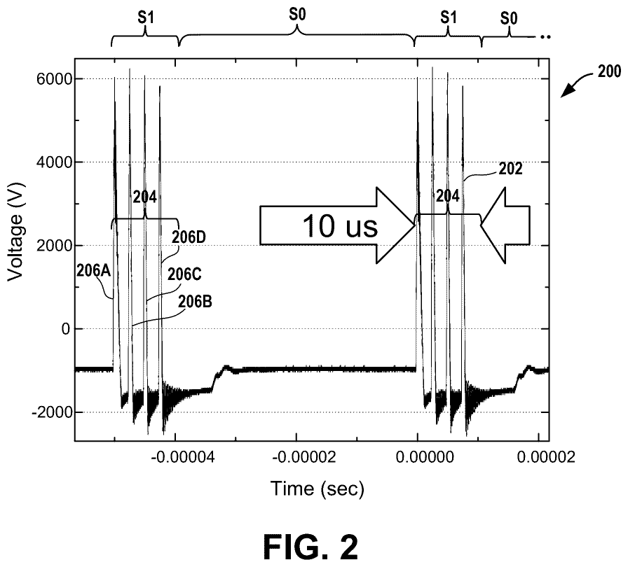

FIG. 2 is an embodiment of a graph 200 to illustrate a change, such as an increase, in a pulse width. The graph 200 plots the parameter of a square pulse waveform 202 versus the time t. The parameter of the square pulse waveform 202 is plotted on a y-axis and the time t is plotted on an x-axis. As shown in the graph 200, the square pulse waveform 202 has a pulse width 204, which is greater than the pulse width 104 (FIG. 1A). For example, a state S1 of the square pulse waveform 202 has four pulses, such as a pulse 206A, a pulse 206B, a pulse 206C, and a pulse 206D, and the state S1 of the square pulse waveform 102 has the two pulses 106A and 106B (FIG. 1A). In the example, the state S1 of the square pulse waveform 202 has the pulse width 204 that is twice the pulse width 104 (FIG. 1A). Moreover, the square pulse waveform 202 has a state S0. In the state S0, the square pulse waveform 202 excludes a pulse but includes noise.

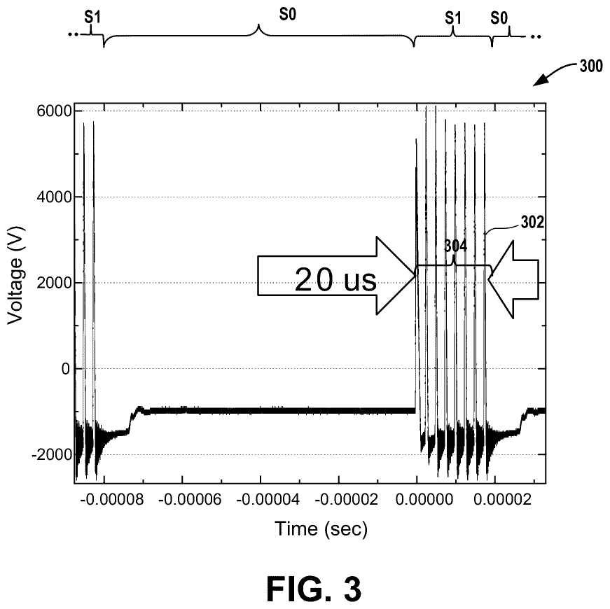

FIG. 3 is an embodiment of a graph 300 to illustrate a further change, such as an increase, in a pulse width from the pulse width 204 (FIG. 2). The graph 300 plots the parameter of a square pulse waveform 302 versus the time t. The parameter of the square pulse waveform 302 is plotted on a y-axis and the time t is plotted on an x-axis. As shown in the graph 300, the square pulse waveform 302 has a pulse width 304, which is greater than the pulse width 202. For example, a state S1 of the square pulse waveform 302 has eight pulses and the state S1 of the square pulse waveform 202 has the four pulses. In the example, the state S1 of the square pulse waveform 302 has the pulse width 304 that is twice the pulse width 204 (FIG. 2). Moreover, the square pulse waveform 302 has a state S0. In the state S0, the square pulse waveform 302 excludes a pulse but includes noise.

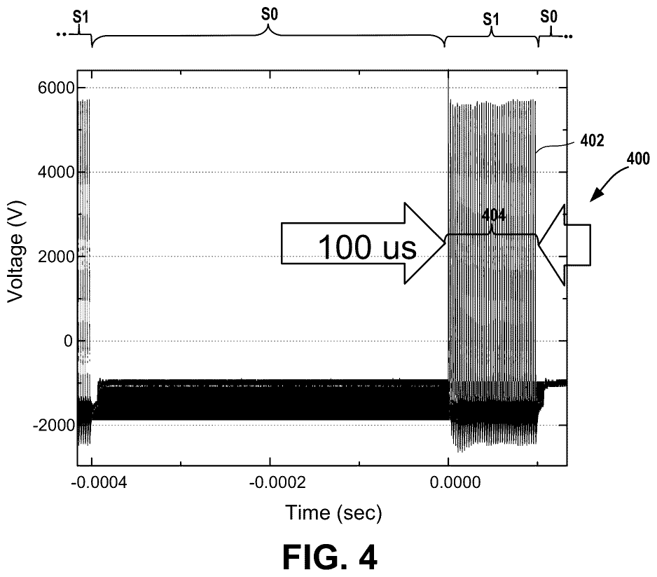

FIG. 4 is an embodiment of a graph 400 to illustrate a change, such as an increase, in a pulse width, compared to the pulse width 304 (FIG. 3). The graph 400 plots the parameter of a square pulse waveform 402 versus the time t. The parameter of the square pulse waveform 402 is plotted on a y-axis and the time t is plotted on an x-axis. As shown in the graph 400, the square pulse waveform 402 has a pulse width 404, which is greater than the pulse width 304. For example, a state SI of the square pulse waveform 402 has a number of pulses greater than eight and the state S1 of the square pulse waveform 302 has the eight pulses. In the example, the state S1 of the square pulse waveform 402 has the pulse width 404 that is greater than the pulse width 304.

Moreover, the square pulse waveform 402 has a state S0. In the state S0, the square pulse waveform 402 excludes a pulse but includes noise.

It should be noted that each of the pulse widths 104, 204, 304, and 404 provides the same duty cycle. For example, the duty cycle of each of the square pulse waveforms 102 through 402 is equal, such as 20 percent. To illustrate, the duty cycle of a square pulse waveform is a percentage of a time period of a cycle of the clock signal for which the state S1 of the square pulse waveform occurs.

In an embodiment, different duty cycles are provided by different pulse widths of different square pulse waveforms.

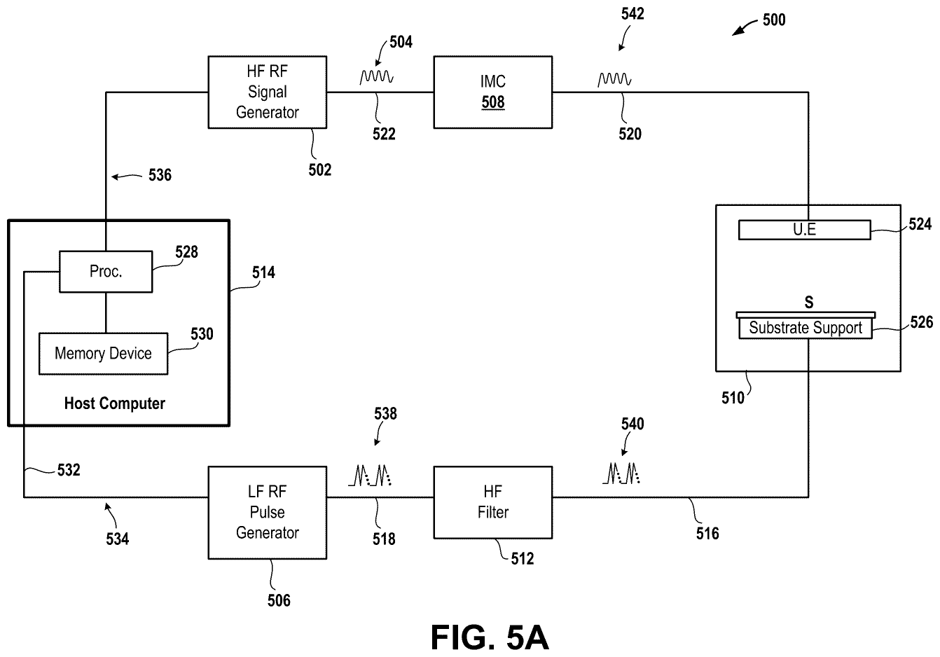

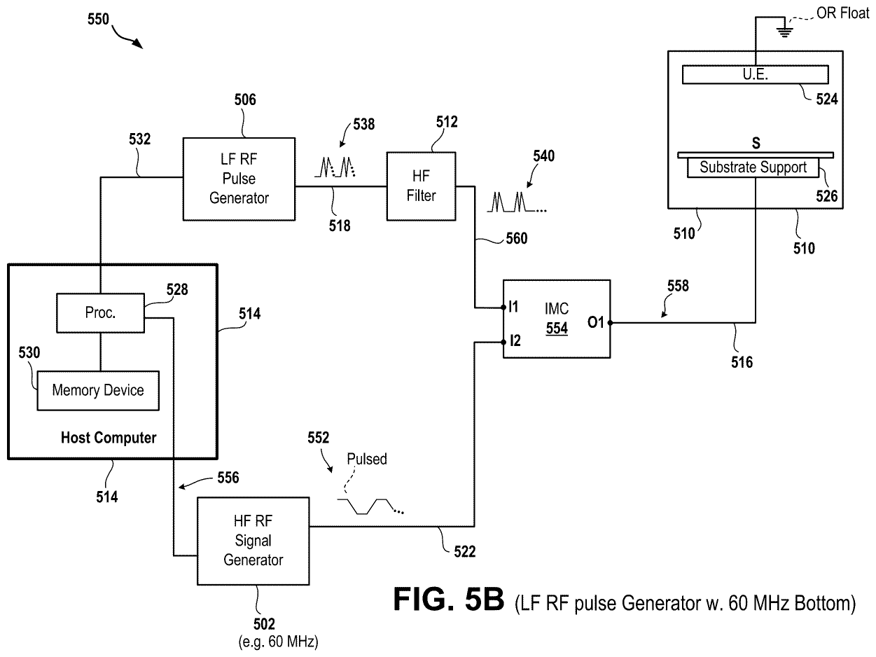

FIG. 5A is a diagram of an embodiment of a system 500 to illustrate use of an HF RF signal generator 502 that generates an RF signal 504 to be used in conjunction with an LF RF pulse generator 506. The RF signal 504 is a continuous waveform. An example of a continuous waveform is a sinusoidal waveform that is not pulsed between multiple states. To illustrate, the continuous waveform has an envelope that does not transition from a high state to a low state or vice versa. To further illustrate, the envelope of the continuous waveform is not a digital pulsed signal. In the illustration, the continuous waveform and not a multi-state sinusoidal RF signal is supplied by the HF RF signal generator 502 because of a difference in a rate of transition of the multi-state sinusoidal RF signal and a rate of transition of a square pulse waveform 538 generated by the LF RF pulse generator 506. In the illustration, the rate of transition between states of the multi-state sinusoidal RF signal is greater than the rate of transition between states of the square pulse waveform 538. The system 500 includes the HF RF signal generator 502, an impedance matching circuit (IMC) 508, a plasma chamber 510, an HF filter 512, the LF RF pulse generator 506 and a host computer 514.

Examples of the host computer 514 include a desktop computer, a laptop computer, a tablet, a smart phone, and a controller. As an example, the HF RF signal generator 502 has an operational high frequency of 27 megahertz (MHz) or 60 MHz. Also, as an example, the LF RF pulse generator 506 has an operational low frequency ranging from 10 kilohertz (kHz) to 800 kHz. To illustrate, the low frequency is a baseline frequency of 400 kHz. To further illustrate, a frequency of operation of the LF RF pulse generator 506 is 400 kHz. An example of the baseline frequency is a fundamental frequency. As an example, the HF filter 512 includes an inductor. As another example, the HF filter 512 is not an impedance matching circuit. To illustrate, the HF filter 512 does not match an impedance of a load coupled to an output of the HF filter 512 with an impedance of a source coupled to an input of the HF filter 512. In the illustration, an example of the load coupled to the output of the HF filter 512 is an RF transmission line 516 and the plasma chamber 510. Further in the illustration, the example of the source coupled to the input of the HF filter 512 includes an RF cable 518 and the LF RF pulse generator 506.

Examples of the impedance matching circuit 508 include a match and an impedance matching network. For example, the impedance matching circuit 508 is a series of circuit components, such as capacitors, inductors, and resistors. The circuit components are coupled to each other. To illustrate, two of the circuit components are coupled to each other in a series or in parallel. The match matches an impedance of a load, such as the plasma chamber 510 and an RF transmission line 520, coupled to an output of the impedance matching circuit 508 with an impedance of a source coupled to an input of the impedance matching circuit 508. An example of the source coupled to the input of the impedance matching circuit 508 includes an RF cable 522 and the HF RF signal generator 502.

The plasma chamber 510 includes an upper electrode 524 and a substrate support 526. Example of the substrate support 526 includes electrostatic chuck (ESC). The substrate support 526 includes a lower electrode. A substrate S, such as a semiconductor wafer is placed on a top surface of the substrate support 526 for being processed within the plasma chamber 510.

The host computer 514 includes a processor 528 and a memory device 530. The processor 528 is coupled to the memory device 530. Examples of the processor 528 include an application specific integrated circuit (ASIC), a programmable logic device (PLD), and a central processing unit (CPU). Examples of the memory device 530 include a read-only memory (ROM) and a random access memory (RAM).

The processor 528 is coupled to an input of the HF RF signal generator 502 via a transfer cable, which is described below. An output of the HF RF signal generator 502 is coupled via the RF cable 522 to the input of the impedance matching circuit 508. The output of the impedance matching circuit 508 is coupled via the RF transmission line 522 the upper electrode 524.

Moreover, the processor 528 is coupled via a transfer cable 532 to an input of the LF RF pulse generator 506. An example of a transfer cable includes a cable that facilitates a serial transfer of data, or a parallel transfer of data, or a transfer of data via a universal serial bus (USB) protocol. An output of the LF RF pulse generator 506 is coupled to the input of the HF filter 512. The output of the of HF filter 512 is coupled via the RF transmission line 516 to the lower electrode of the substrate support 526.

The processor 528 generates and sends a recipe signal 534 via the transfer cable 532 to the input of the LF RF pulse generator 506. The recipe signal 534 includes information, such as a pre-determined number of pulses of the square pulse waveform 538 to be generated by the LF RF pulse generator 506 during each cycle of the clock signal. As an example, the processor 528 generates the clock signal, sends the clock signal via the transfer cable 534 to the LF RF pulse generator 506, and sends the clock signal to the HF RF signal generator 502. The predetermined number of pulses of the square pulse waveform 538 defines a pulse width of a state of the square pulse waveform 528. In addition, the information within the recipe signal 534 includes a statistical amplitude of the parameter of the pre-determined number of pulses, of the square pulse waveform 538, to be generated during each cycle of the clock signal. An example of the statistical amplitude includes an average amplitude or a median amplitude. Moreover, the information within the recipe signal 534 includes a statistical amplitude of the parameter of the state S0 of the square pulse waveform 538. Also, the information within the recipe signal 534 includes a statistical pulse width, such as the pulse width 104 or 204 or 304 or 404 (FIGS. 1A, 2, 3, and 4), which is a time interval, between two consecutive pulses of the pre-determined number of pulses during each cycle of the clock signal. In addition, the information within the recipe signal 534 includes a statistical sub-pulse width, such as the sub-pulse width 110 (FIG. 1A), of the square pulse waveform 538 and a statistical pulse-to-pulse width, such as the pulse-to-pulse width 112 (FIG. 1A), of the square pulse waveform 538. Examples of the square pulse waveform 538 include the square pulse waveform 102 (FIG. 1A), the square pulse waveform 202 (FIG. 2), the square pulse waveform 302 (FIG. 3), and the square pulse waveform 402 (FIG. 4).

Moreover, the information within the recipe signal 534 includes a start time at which a first pulse of the square pulse waveform 528 is to be generated during each cycle of the clock signal. The first pulse is generated first in a series of pulses of a state of the square pulse waveform 528. The start time or the number of pulses or a combination thereof for the state of the square pulse waveform 528 provides a phase of an envelope of multiple pulses of the state of the square pulse waveform 528. For example, the start time at which the first pulse of the square pulse waveform 528 is to be generated is a phase, such as a time of a transition, of the envelope from one parameter level to another parameter level. Also, in the example, an end time at which a last pulse in the series of pulses of the state of the square pulse waveform 528 ends is another example of the phase of the envelope of the multiple pulses of the state of the square pulse waveform 528. In the example, the end time at which the last pulse ends depends on the number of pulses of the series of the state of the square pulse waveform 528.

Also, the processor 528 generates and sends a recipe signal 536 to the HF RF signal generator 502. The recipe signal 536 includes information, such as a power level and a frequency level, of the parameter of the RF signal 504 to be generated by the HF RF signal generator 502. An example of the frequency level is a fundamental frequency. An example of the power level is a peak-to-peak amplitude or a zero-to-peak amplitude. An example, the recipe signal 506 includes a single value of the power level and a value of the frequency level. To illustrate, the information within the recipe signal 536 indicates that the RF signal 506 is the continuous waveform having a single state. To further illustrate, the information within the recipe signal 536 indicates that the RF signal 506 does not transition from a first state to a second state. In the further illustration, the first state of a multi-state sinusoidal signal has a different power level than a power level of the second state of the multi-state sinusoidal signal. In the further illustration, a rate of transition from the first state of the multi-state sinusoidal signal to the second state of the multi-state sinusoidal signal is less than the rate of transition from the state S1 to the state S0 of the square pulse waveform 538 and a rate of transition from the second state of the multi-state sinusoidal signal is less than the rate of transition from the state S0 to the state S1 of the square pulse waveform 538.

Upon receiving the recipe signal 534, a processor of the LF RF pulse generator 506 stores the information received within the recipe signal 534 within a memory device of the LF RF pulse generator 506. Similarly, upon receiving the recipe signal 536, a processor of the HF RF signal generator 502 stores the information received within the recipe signal 536 within a memory device of the HF RF signal generator 502.

In addition, the processor 528 generates a trigger signal, sends the trigger signal to the HF RF signal generator 502, and sends the trigger signal via the transfer cable 532 to the LF RF pulse generator 506. An example of the trigger signal is a single pulse.

Upon receiving the trigger signal, the processor of the LF RF pulse generator 506 accesses the information received within the recipe signal 534 from the memory device of the LF RF pulse generator 506, and controls multiple signal components of the LF RF pulse generator 506 to generate the square pulse waveform 538 based on the recipe signal 534. Examples of the signal components are provided below. The LF RF pulse generator 506 sends the square pulse waveform 538 via the RF cable 518 to the input of the HF filter 512. The HF filter 512 modifies an impedance of the square pulse waveform 538 to provide a modified square pulse waveform 540. As an example, the modified square pulse waveform 540 is similar in shape to or has the same shape as that of the square pulse waveform 538. For example, the modified square pulse waveform 540 has a series of pulses having a state S1 immediately followed by a state S0 having no pulses during each cycle of the clock signal. The HF filter 512 sends the modified square pulse waveform 540 via the RF transmission line 516 to the lower electrode of the substrate support 526.

Similarly, upon receiving the trigger signal, the processor of the HF RF signal generator 502 accesses the information received within the recipe signal 536 from the memory device of the HF RF signal generator 502 and controls an RF power supply of the HF RF signal generator 502 to generate the RF signal 504 based on the recipe signal 536. The HF RF signal generator 502 sends the RF signal 504 via the RF cable 522 to the impedance matching circuit 508. The impedance matching circuit 508 matches the impedance of the load coupled to the output of the impedance matching circuit 508 with the impedance of the source coupled to the input of the impedance matching circuit 508 to provide a modified RF signal 542. An example of the modified RF signal 542 is a continuous waveform that excludes more than a single state. To illustrate, the modified RF signal 542 has a similar shape or the same shape as that of the RF signal 504. The modified RF signal 542 is sent from the output of the impedance matching circuit 508 via the RF transmission line 520 to the upper electrode 524.

When one or more process gases are supplied to the plasma chamber 510 in addition to the modified RF signal 542 and the modified square pulse waveform 540, plasma is stricken or maintained within the plasma chamber 510. Examples of the one or more process gases include an oxygen containing gas, a fluorine containing gas, and a combination thereof. The plasma is used to process the substrate S. Examples of processing the substrate S includes depositing materials on the substrate S, or etching the substrate S, or sputtering the substrate S, or cleaning the substrate S.

RF power is reflected from the plasma chamber 510 via the RF transmission line 516 towards the HF filter 512. The HF filter 512 filters out the high frequency from the RF power to output a filtered signal. The filtered signal is provided from the HF filter 512 via the RF cable 518 to the LF RF pulse generator 506. The filtered signal does not damage components of the LF RF pulse generator 506.

In an embodiment in which the square pulse waveform 152 (FIG. 1B) is to be generated by the LF RF pulse generator 506 in which the state S0 has multiple pulses, another recipe signal (not shown) is generated by the processor 528. Information received within the other recipe signal (not shown) is the same as the information received within the recipe signal 534 except that the information within the other recipe signal (not shown) includes a statistical amplitude, such as an average amplitude or a mean amplitude, of each pulse of the state S0, a predetermined number of pulses during the state S0, a sub-pulse width, such as an average sub-pulse width, of each pulse during the state S0, and a pulse-to-pulse width, such as an average pulse-to-pulse width, between two consecutive pulses during the state S0. It should be noted that the statistical amplitude of the state S0 is less than the statistical amplitude of the state S1 of the square pulse waveform 152. For example, the statistical amplitude of the state S0 is less than the statistical amplitude of the state S1 of the square pulse waveform 152 by at least 10% and at most 90%.

FIG. 5B is a diagram of an embodiment of a system 550 to illustrate use of the HF RF signal generator 502 that generates an RF signal 552 used in conjunction with the LF RF pulse generator 506. The RF signal 552 is a multi-state sinusoidal signal. The system 550 is similar to the system 500 except that in the system 550, the HF RF signal generator 502 is coupled to the substrate support 526 via an impedance matching circuit 554 and the upper electrode 524 is coupled to a ground potential.

An example of an impedance matching circuit is a network of circuit components, such as capacitors, or inductors, or resistors, or a combination thereof. To illustrate, the impedance matching circuit 554 includes an input I1, another input 12, an output O1, a first branch circuit including a set of network components, such as capacitors and inductors, and a second branch circuit includes a set of network components. The first branch circuit is coupled between the input Il and the output O1 and the second branch circuit is coupled between the input 12 and the output 02.

The HF filter 512 is coupled to the input Il of the impedance matching circuit 554 via an RF cable 560. Also, the HF RF signal generator 502 is coupled to the input 12 of the impedance matching circuit 554 via the RF cable 522. The output O1 of the impedance matching circuit 554 is coupled via the RF transmission line 516 to the substrate support 526.

The processor 528 generates and sends a recipe signal 556 to the HF RF signal generator 502. The recipe signal 556 includes information, such as a duty cycle, multiple parameter levels and a frequency level, of the parameter of the RF signal 552 to be generated by the HF RF signal generator 502. An example, the recipe signal 556 includes a multiple values of the parameter levels, a first time of initiation of transition from a first one of the parameter levels to a second one of the parameter levels, a second time of initiation of transition from the second parameter level to the first parameter level, and a value of the frequency level. In the example, a time period between the first time of initiation and the second time of initiation is the duty cycle of an envelope of the parameter of the RF signal 552. To illustrate, the information within the recipe signal 556 indicates that the RF signal 552 is a pulsing waveform having multiple states. To further illustrate, the information within the recipe signal 556 indicates that the RF signal 552 starts transitioning from a first state, such as the first parameter level, to a second state, such as the second parameter level, at the first time of initiation and that the RF signal 552 starts transitioning from the second state to the first state at the second time of initiation. In the further illustration, the first state of the multi-state sinusoidal signal has the first parameter level, which is different than the second parameter level of the second state of the multi-state sinusoidal signal. In the further illustration, the first rate of transition from the first state of the multi-state sinusoidal signal to the second state of the multi-state sinusoidal signal is less than the rate of transition from the state S1 to the state S0 of the square pulse waveform 538 and the second rate of transition from the second state of the multi-state sinusoidal signal is less than the rate of transition from the state S0 to the state S1 of the square pulse waveform 538. Upon receiving the recipe signal 556, the processor of the HF RF signal generator 502 stores the information received within the recipe signal 536 within the memory device of the HF RF signal generator 502.

The HF filter 512 sends the modified square pulse waveform 540 to the impedance matching circuit 554 via the RF cable 560. Also, upon receiving the trigger signal, the processor of the HF RF signal generator 502 accesses the information received within the recipe signal 556 from the memory device of the HF RF signal generator 502 and controls the RF power supply of the HF RF signal generator 502 to generate the RF signal 552 based on the recipe signal 556. For example, the RF signal 552 has the parameter levels received within the recipe signal 556, the frequency level, and the duty cycle during each cycle of the clock signal.

The RF signal 552 is sent from the HF RF signal generator 502 to the impedance matching circuit 554 via the RF cable 522. The impedance matching circuit 554 matches an impedance of a load coupled to the output O1 of the impedance matching circuit 554 with an impedance of a source coupled to the inputs I1 and 12 of the impedance matching circuit 554 to output a modified signal 558 at the output O1 of the impedance matching circuit 554. An example of the source coupled to the inputs 11 and 12 of the impedance matching circuit 554 includes the RF cable 560, the HF filter 512, the RF cable 518, the LF RF pulse generator 506, the RF cable 522, and the HF RF signal generator 502. An example of the load coupled to the output O1 of the impedance matching circuit 554 includes the RF transmission line 516 and the plasma chamber 510. To illustrate, the first branch circuit of the impedance matching circuit 554 modifies an impedance of the modified square pulse waveform 540 to output a modified square pulse waveform at an output of the first branch circuit and the second branch circuit modified an impedance of the RF signal 552 to output a modified RF signal at an output of the second branch circuit of the impedance matching circuit 554. In the illustration, the modified square pulse waveform and the modified RF signal are combined, such as added, at the output O1 to provide the modified signal 558. In the illustration, the first and second branch circuits are coupled to each other at the output O1. The modified signal 558 is sent via the RF transmission line 516 to the substrate support 526. When the one or more process gases are supplied to the plasma chamber 510 in addition to the modified signal 558, plasma is stricken or maintained within the plasma chamber 510.

In an embodiment, in the system 550, instead of coupling the upper electrode 524 to the ground potential, the upper electrode 524 is floating. For example, the upper electrode 524 is at a floating potential. To illustrate, the upper electrode 524 is not connected to the ground potential or to a power source, such as the HF RF signal generator 502.

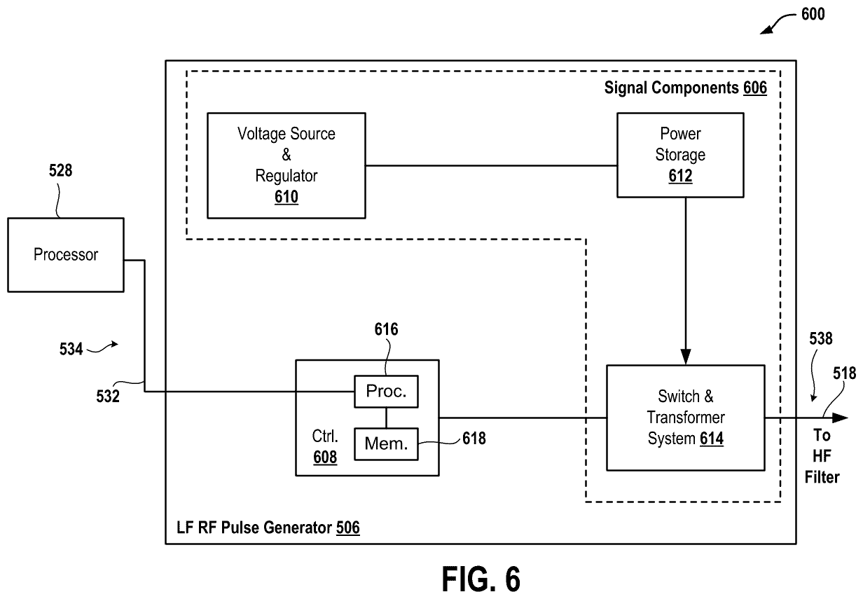

FIG. 6 is an embodiment of system 600 that includes the processor 528 and the LF RF pulse generator 506. The LF RF pulse generator 506 includes signal components 606 and a controller 608. The signal components 606 include a voltage and source regulator 610, a power storage 612, and a switch and transformer system 614. As an example, RF voltage oscillations, as described herein, is noise due to one or more of the signal components 606.

An example of the voltage source and regulator 610 includes a combination of a voltage supply, such as a direct current (DC) voltage supply, and a voltage regulator, such as a variable resistor. The voltage supply is coupled to the voltage regulator. An example of the switch and transformer system 614 includes a combination of a switch, such as a solid-state switch, and a transformer. An illustration of the solid-state switch is a transistor or a group of transistors. The solid-state switch is coupled to the transformer. As an example, the transformer includes a primary winding and a secondary winding. An example of the power storage 612 includes a capacitor.

As an example, the controller 608 includes a processor 616 and a memory device 618. The processor 616 is coupled to the memory device 618. As another example, the controller 608 is an ASIC or a PLD.

The processor 616 is coupled to the processor 528 via the transfer cable 532. The processor 616 is coupled to the switch of the switch and transformer system 614. The voltage regulator of the voltage source and regulator 610 is coupled to the power storage 612.

Moreover, the power storage 612 is coupled to the transformer and the switch is coupled to the transformer. For example, the power storage 612 is coupled to a first end of the primary winding and the switch is coupled to a second end of the primary winding. The secondary winding of the transformer is coupled to the RF cable 518.

Upon receiving the information within the recipe signal 534 from the processor 528, the processor 616 stores the information within the memory device 618. The voltage supply generates a voltage signal and supplies the voltage signal to the voltage regulator. The voltage regulator regulates the voltage signal, such as maintains the voltage signal to match a pre-determined voltage signal, to output a regulated voltage signal, and sends the regulated voltage signal to the power storage 612. The power storage 612 stores a charge according to the regulated voltage signal.

Moreover, in response to receiving the trigger signal from the processor 528, during a cycle n of the clock signal, the processor 616 accesses the information received within the recipe signal 534, such as the sub-pulse width, the pulse-to-pulse width, the pulse width, the start time, and the pre-determined number of pulses, of the square pulse waveform 538 from the memory device of the controller 306, generates an on command signal, and sends the on command signal to the switch at the start time, where n is a positive integer. When the on command signal is received during the cycle n of the clock signal, the switch turns on and a switch current signal generated to discharge the charge stored in the power storage 612 is supplied to the primary winding of the transformer for the time period of the sub-pulse width, such as the sub-pulse width 110 (FIG. 1A). During the cycle n of the clock signal, the secondary winding transforms, such as increases or decreases, an amount of voltage of the switch current signal to a different amount to output a transformed amount of voltage to start generating the pulse, such as the pulse 106A (FIG. 1A). The transformed amount of voltage is a voltage of the pulse.

During the cycle n of the clock signal, at the end of the time period of the sub-pulse width, the processor 616 generates an off command signal, and sends the off command signal to the switch. Also, during the cycle n, upon receiving the off command signal, the switch turns off and the supply of the switch current signal to the primary winding stops. Further, during the cycle n, the supply of the switch current signal stops, the voltage applied by the switch current signal drops to reduce the voltage across the primary winding. During the cycle n, when the voltage across the primary winding reduces, the transformed amount of voltage reduces to end the generation of the pulse having the sub-pulse width to output a reduced transformed amount of voltage. Also, during the cycle n, the reduced transformed amount of voltage is of the RF voltage oscillations, such as the RF voltage oscillations 108A (FIG. 1A), that immediately follow the pulse, such as the pulse 106A (FIG. 1A).

Also, during the cycle n of the clock signal, the processor 616 controls the switch to be off until an end of the time period of the pulse-to-pulse width, such as the pulse-to-pulse width 112 (FIG. 1A). During the cycle n of the clock signal, after the end of the time period of the pulse-to-pulse width, the processor of the controller 306 controls the switch to be turned back on for the time period of the sub-pulse width, such as the sub-pulse width 110 (FIG. 1A), and further controls the switch to be turned back off at an end of the time period of the sub-pulse width 110 to complete generation of a consecutive pulse, such as the pulse 106B (FIG. 1A). In this manner, multiple pulses and multiple RF voltage oscillations of the state S1 of the square wave signal 538 are generated during the cycle n.

Moreover, after the switch is controlled to be turned back off at the end of the time period of the sub-pulse width, the processor 616 controls the switch to remain off until an end of the time period of the cycle n of the clock signal. When the switch is off, RF oscillations, such as the RF oscillations 108B, occur and are followed by additional RF oscillations, such as RF oscillations 116, of the state S0 of the square pulse waveform, such as the square pulse waveform 102. The RF oscillations 116 transition from a lower voltage, such as a negative voltage, to a higher voltage, such as a voltage closer to zero volts, due to a discharge in capacitance at the substrate support 526 (FIG. 5A). The lower voltage is less than the higher voltage.

In a similar manner, the switch is controlled by the processors 528 and 616 during each following cycle, such as a cycle (n+1), a cycle (n+2), and so on of the clock signal to generate the states S1 and S0 of the square pulse waveform during each of the following cycles of the clock signal. For example, upon receiving the clock signal indicating that the cycle (n+1) of the clock signal has started, the processor 616 controls the switch to turn on to generate pulses, such as the pulses 114A and 114B, during the cycle (n+1).

To modify the pulse width, the information within the recipe signal 534 is modified by the processor 528 to increase or decrease the pre-determined number of pulses. The information within the recipe signal 534 is modified to output a modified recipe signal to the processor 616. Upon receiving the modified recipe signal, the processor 616 controls the switch and transformer system 614 to generate another square pulse waveform, such as the square pulse waveform 202 (FIG. 2) or 302 (FIG. 3) or 402 (FIG. 4), based on the modified recipe signal in the same manner in which the square pulse waveform 102 is generated based on the recipe signal 534.

When the same duty cycle is to be maintained with an increase in a number of pulses of the square pulse waveform 538 during each cycle of the clock signal, the processor 528 modifies a time period of each cycle of the clock signal. For example, to maintain the same duty cycle when a number of the pulses of the square pulse waveform 538 increase from two to four, a time period of occurrence of each cycle of the clock signal is increased by the same percentage as that of a percentage of the increase in the time period of occurrence from the two pulses to the four pulses. To illustrate, the time period of occurrence of each cycle of the clock signal increases by 100 percent when the number of pulses increase from two to four. In the illustration, the number of occurrence of the pulses from two to four is a 100% increase.

In one embodiment in which the square pulse waveform 152 (FIG. 1B) in which the state S0 has multiple pulses is to be generated, the processor 528 sends the other recipe signal (not shown) to the processor 616 via the transfer cable 532. Upon receiving the other recipe signal, the processor 616 controls the switch to be turned on and off to generate the state S0 of the square pulse waveform 152 in the same manner to that in which the state S1 of the square pulse waveform 152 is generated except that during the state S0, the amplitudes, such as peak-to-peak amplitudes or zero-to-peak amplitudes, of each pulse of the state S0 of the square pulse waveform 152 is less than the amplitude, such as the high amplitudes, of each pulse of the state S1 of the square pulse waveform 152.

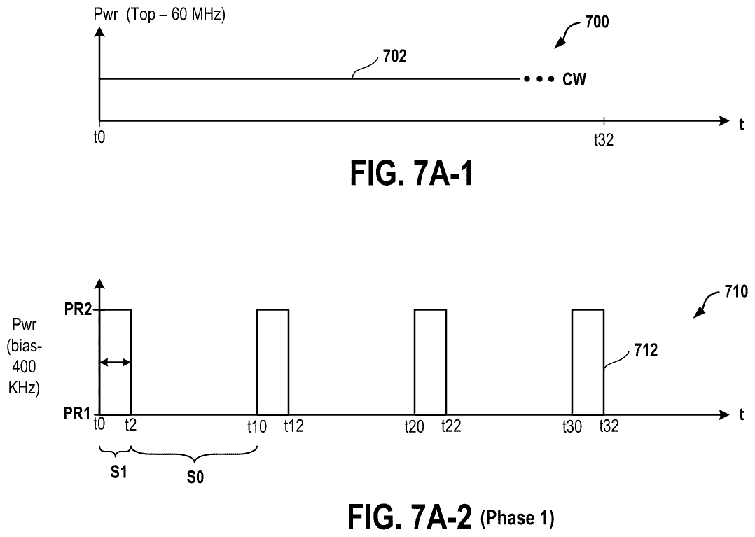

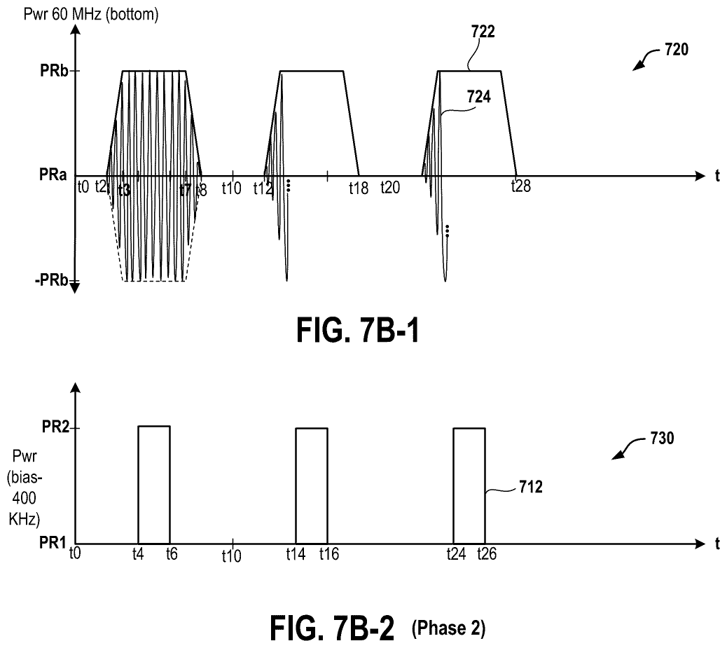

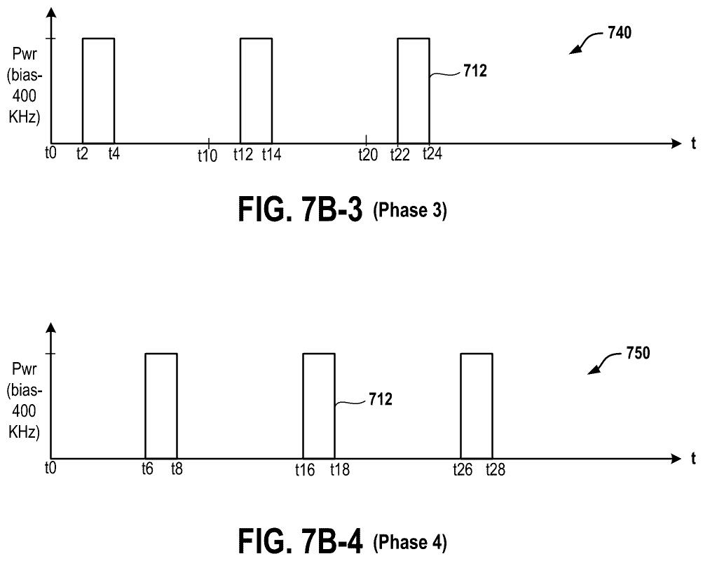

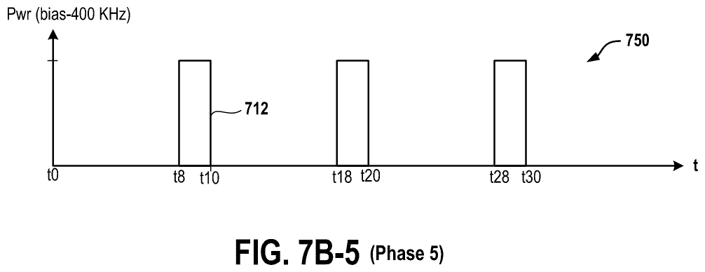

FIG. 7A-1 is an embodiment of a graph 700 to illustrate the continuous waveform of the RF signal 504 (FIG. 5A). The graph 700 plots the parameter of the RF signal 504 versus the time t. For example, an envelope 702 of the RF signal 504 is plotted on a y-axis and the time t is plotted on an x-axis. The envelope 702, such as a peak-to-peak amplitude or a zero-to-peak amplitude, of the graph 700 is constant or substantially constant.

FIG. 7A-2 is an embodiment of a graph 710 to illustrate an envelope 712 of the square pulse waveform 538 (FIG. 6). The graph 710 plots the envelope 712 of the parameter of the square pulse waveform 538 on a y-axis and the time t on an x-axis. The envelope 712 encompasses multiple pulses of the state S1 of the square pulse waveform 538.

As shown, the envelope 712 is of a rectangular shape during the state S1. However, a statistical amplitude during the state S1 of the square pulse waveform 538 can be modified to achieve a square-shaped envelope.

The envelope 712 has a variable pulse width. For example, a pulse width of the state S1 of the envelope 712 can be modified by modifying a number of pulses during the state S1 of the square pulse waveform 538.

Also, the envelope 712 has a phase 1. For example, during the first cycle of the clock signal, the envelope 712 transitions from a parameter level PR1 to a parameter level PR2 at the time t0 and transitions back to the parameter level PRI from the parameter level PR2 at the time t2. In the example, each of the times t0 and t2 is an example of the phase 1. The parameter level PR2 is greater than the parameter level PR1, the parameter level PR1 is a real number, and the parameter level PR2 is a different real number. It should be noted that envelope 712 remains at the parameter level PR2 from the time t0 to the time t2, and remains at the parameter level PRI from the time t2 to the time t10 during the first cycle of the clock signal. The time t0 is an example of the start time during the first cycle and the time t2 is an example of the end time during the first cycle. In a similar manner, pulsing, such as transitioning, between the parameter levels PR1 and PR2 of the envelope 712 repeat during each following cycle, such as the cycle 2, of the clock signal.

FIG. 7B-1 is an embodiment of a graph 720 to illustrate an envelope 722 of the parameter of an RF signal 724 that is generated by the HF RF signal generator 502 of FIG. 5B. The graph 720 plots the envelope 722 of the parameter level of the RF signal 724 on a y-axis and the time t on an x-axis. The RF signal 724 is an example of the RF signal 552 (FIG. 5B). The HF RF signal generator 502 pulses the envelope 722 between a parameter level PRb and a parameter level −PRb, where PRb is a positive real number. The parameter level PRb is greater than a parameter level PRa, which is greater than the parameter level −PRb, where PRa is a positive real number. The HF RF signal generator 502 is pulsed between the parameter levels PRb and −PRb in level-to-level pulsing. The pulsing between the parameter levels PRb and −PRb is represented as being pulsed between the parameter levels PRa and PRb in zero-to-level pulsing.

During the first cycle of the clock signal, the RF signal 724 transitions starting from the time t2 to the time t3. The RF signal 724 transitions from the parameter level PRa to the parameter level PRb during a time period between the times t2 and t3, and remains at the parameter level PRb from the time t3 to the time t7. The RF signal 724 transitions starting from the time t7 to the time t8. The RF signal 724 transitions from the parameter level PRb to the parameter level PRa during a time period between the times t7 and t8, and remains at the parameter level PRa from the time t8 to the time t10 during the first cycle of the clock signal. Similarly, the RF signal 724 transitions between the parameter levels PRa and PRb during each following cycle of the clock signal, and during each of the following cycle, the envelope 712 has the phase 1.

FIG. 7B-2 is an embodiment of a graph 730 to illustrate a change in phase of the envelope 712 of the square pulse waveform 538 (FIG. 6) from the phase 1 to a phase 2. The graph 730 plots the envelope 712 of the parameter of the square pulse waveform 538 on a y-axis and the time t on an x-axis.

The envelope 712 has the phase 2, which is different from the phase 1. For example, the phase 2 lags the phase 1. To illustrate, during the first cycle of the clock signal, the envelope 712 transitions from the parameter level PR1 to the parameter level PR2 at the time t4 and transitions back to the parameter level PRI from the parameter level PR2 at the time t6. In the example, each of the times t4 and t6 is an example of the phase 2. Also, the time t4 is an example of the start time during the first cycle of the clock signal and the time t6 is an example of the end time during the first cycle. It should be noted that envelope 712 remains at the parameter level PRI from the time t0 to the time t4, remains at the parameter level PR2 from the time t4 to the time t6, and remains at the parameter level PRI from the time t6 to the time t10 during the first cycle of the clock signal. In a similar manner, pulsing, such as transitioning, between the parameter levels PR1 and PR2 of the envelope 712 repeat during each following cycle, such as the cycle 2, of the clock signal, and during each of the following cycle, the envelope 712 has the phase 2.

FIG. 7B-3 is an embodiment of a graph 740 to illustrate a change in phase of the envelope 712 of the square pulse waveform 538 (FIG. 6) from the phase 1 or the phase 2 to a phase 3. The graph 740 plots the envelope 712 of the parameter of the square pulse waveform 538 on a y-axis and the time t on an x-axis.

The envelope 712 has the phase 3, which is different from the phase 1 and the phase 2. For example, the phase 3 lags the phase 1 and leads the phase 2. To illustrate, during the first cycle of the clock signal, the envelope 712 transitions from the parameter level PR1 to the parameter level PR2 at the time t2 and transitions back to the parameter level PRI from the parameter level PR2 at the time t4. In the example, each of the times t2 and t4 is an example of the phase 3. Also, the time t2 is an example of the start time during the first cycle of the clock signal and the time t4 is an example of the end time during the first cycle. It should be noted that envelope 712 remains at the parameter level PRI from the time t0 to the time t2, remains at the parameter level PR2 from the time t2 to the time t4, and remains at the parameter level PRI from the time t4 to the time t10 during the first cycle of the clock signal. In a similar manner, pulsing, such as transitioning, between the parameter levels PR1 and PR2 of the envelope 712 repeat during each following cycle, such as the cycle 2, of the clock signal, and during each of the following cycle, the envelope 712 has the phase 3.

FIG. 7B-4 is an embodiment of a graph 740 to illustrate a change in phase of the envelope 712 of the square pulse waveform 538 (FIG. 6) from the phase 1 or the phase 2 or the phase 3 to a phase 4. The graph 740 plots the envelope 712 of the parameter of the square pulse waveform 538 on a y-axis and the time t on an x-axis.

The envelope 712 has the phase 4, which is different from the phase 1, the phase 2, and the phase 3. For example, the phase 4 lags the phase 1, the phase 2, and the phase 3. To illustrate, during the first cycle of the clock signal, the envelope 712 transitions from the parameter level PR1 to the parameter level PR2 at the time t6 and transitions back to the parameter level PR1 from the parameter level PR2 at the time t8. In the example, each of the times t6 and t8 is an example of the phase 4. Also, the time t6 is an example of the start time during the first cycle of the clock signal and the time t8 is an example of the end time during the first cycle. It should be noted that envelope 712 remains at the parameter level PRI from the time t0 to the time t6, remains at the parameter level PR2 from the time t6 to the time t8, and remains at the parameter level PRI from the time t8 to the time t10 during the first cycle of the clock signal. In a similar manner, pulsing, such as transitioning, between the parameter levels PR1 and PR2 of the envelope 712 repeat during each following cycle, such as the cycle 2, of the clock signal, and during each of the following cycle, the envelope 712 has the phase 4.

FIG. 7B-5 is an embodiment of a graph 750 to illustrate a change in phase of the envelope 712 of the square pulse waveform 538 (FIG. 6) from the phase 1 or the phase 2 or the phase 3 or the phase 4 to a phase 5. The graph 750 plots the envelope 712 of the parameter of the square pulse waveform 538 on a y-axis and the time t on an x-axis.

The envelope 712 has the phase 5, which is different from the phase 1, the phase 2, the phase 3, and the phase 4. For example, the phase 5 lags the phase 1, the phase 2, the phase 3, and the phase 4. To illustrate, during the first cycle of the clock signal, the envelope 712 transitions from the parameter level PR1 to the parameter level PR2 at the time t8 and transitions back to the parameter level PRI from the parameter level PR2 at the time t10. In the example, each of the times t8 and t10 is an example of the phase 5. Also, the time t8 is an example of the start time during the first cycle of the clock signal and the time t10 is an example of the end time during the first cycle. It should be noted that envelope 712 remains at the parameter level PRI from the time t0 to the time t8 and remains at the parameter level PR2 from the time t8 to the time t10 during the first cycle of the clock signal. In a similar manner, pulsing, such as transitioning, between the parameter levels PR1 and PR2 of the envelope 712 repeat during each following cycle, such as the cycle 2, of the clock signal, and during each of the following cycle, the envelope 712 has the phase 5.

It should be noted that the envelope 712 has the phases 1 through 5 relative to a phase of the envelope 720 (FIG. 7B-1). As an example, each of a time period between the times t2 and t3 and a time period between the times t7 and t8 is an example of a phase of the envelope 720.

FIG. 8 is an embodiment of a graph 800 to illustrate that an etch rate (ER) of etching the substrate S changes with a change in a pulse width of a square pulse waveform. The graph 800 plots the etch rate on a y-axis and the pulse width is on an x-axis.

An example of the pulse width at a point 802 on the graph 800 is the pulse width 104 (FIG. 1A), an example of the pulse width at a point 804 on the graph 800 is the pulse width 204 (FIG. 2), and an example of the pulse width at a point 806 is the pulse width 404 (FIG. 4). As illustrate in the graph 800, with a decrease in the pulse width, there is an increase in the etch rate.

FIG. 9 is an embodiment of a graph 900 to illustrate that selectivity of etching a layer of the substrate S changes with a change in a pulse width of a square pulse waveform. The graph 900 plots the selectivity on a y-axis and the pulse width on an x-axis. As an example, the selectivity is a ratio of an etch rate of etching a first layer of the substrate S to an etch rate of etching a second layer of the substrate S. The first layer is to be etched at a greater rate compared to the second layer.

An example of the pulse width at a point 902 on the graph 900 is the pulse width 104 (FIG. 1A), an example of the pulse width at a point 904 on the graph 900 is the pulse width 204 (FIG. 2), and an example of the pulse width at a point 906 is the pulse width 404 (FIG. 4). As illustrate in the graph 900, with an increase in the pulse width, there is an increase in the selectivity.

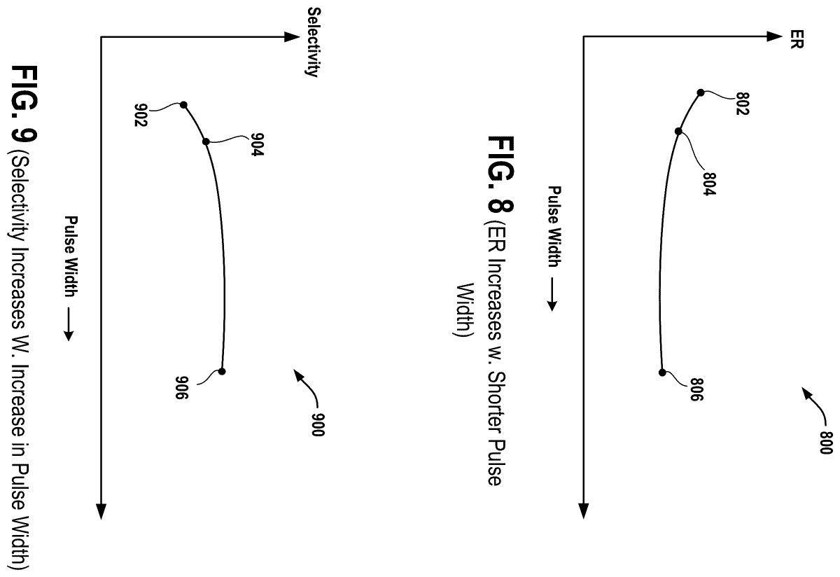

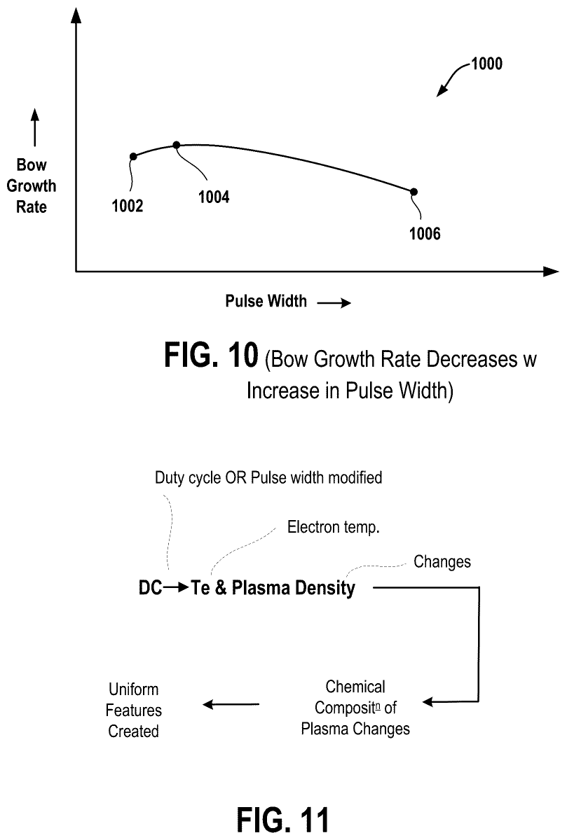

FIG. 10 is an embodiment of a graph 1000 to illustrate that a bow growth rate of a wafer bow of the substrate S changes with a change in a pulse width of a square pulse waveform. The graph 100 plots the bow growth rate on a y-axis and the pulse width on an x-axis.

An example of the pulse width at a point 1002 on the graph 1000 is the pulse width 104 (FIG. 1A), an example of the pulse width at a point 1004 on the graph 1000 is the pulse width 204 (FIG. 2), and an example of the pulse width at a point 1006 is the pulse width 404 (FIG. 4). As illustrate in the graph 1000, with an increase in the pulse width, there is a decrease in the bow growth rate.

FIG. 11 is a diagram to illustrate that with a change in a pulse width of a square pulse waveform, described herein, there is a change in temperature of electrons (Te) of plasma within the plasma chamber 510 (FIG. 5A) and in density of the plasma. For example, the pulse width is increased to increase a rate of change of the temperature of electrons and increase a rate of change of density of the plasma. As another example, the pulse width is decreased to decrease the rate of change of the temperature of electrons and decrease the rate of change of density of the plasma.

The change in the electron temperature and the density modifies a chemical composition of the plasma. As an example, the decrease in the pulse width increases densities of reactants, such as Hydrogen, Chlorine, Fluorine, and Bromine ions, in the plasma and reduces density of a fluorinated carbon (CFx) in the plasma. As another example, the increase in the pulse width decreases the densities of Hydrogen, Chlorine, Fluorine, and Bromine ions and increases the density of the fluorinated carbon. The chemical composition is modified to increase uniformity in features created within the substrate S.

Also, a pulse width of the square pulse waveform can be varied to increase an etch rate as a function of aspect ratio and etch depth. The same gas chemistry is used while the pulse width is varied.

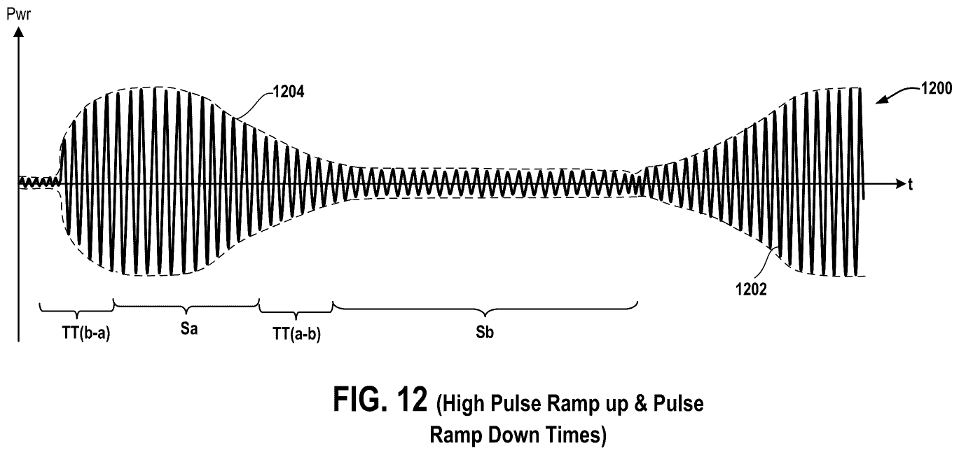

FIG. 12 is an embodiment of a graph 1200 to illustrate that a rate of transition between two states of an RF signal 1202 is greater than a rate of transition between two states of a square pulse waveform, described herein. The graph 1200 plots a power of the RF signal 1202 versus the time t. The power is plotted on a y-axis and the time t is plotted on an x-axis. The RF signal 1202 transitions from a state Sb to a state Sa during a transition time period TT(b-a) and transitions from the state Sa to the state Sb during a transition time period TT(a-b). The transition time period TT(a-b) is larger than a transition time period of transition from the state S1 to the state S0 of the square pulse waveform, described herein. As an example, the transition time period of transition from the state S1 to the state S0 of the square pulse waveform or the transition time period TT(a-b) is sometimes referred to herein as ramp down time. Moreover, the transition time period TT(b-a) is larger than a transition time period of transition from the state S0 to the state S1 of the square pulse waveform, described herein. As an example, the transition time period of transition from the state S0 to the state S1 of the square pulse waveform or the transition time period TT(b-a) is sometimes referred to herein as ramp up time. The slower transition time periods associated with the RF signal 1202 creates limitations and the limitations are removed by use of the square pulsed waveform, described herein.

It should be noted that although the above-embodiments are described with reference to a square pulse waveform, in some embodiments, the terms triangular pulse waveform, saw-tooth pulse waveform, and square pulse waveform are used herein interchangeably.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment, described above, are combined with one or more features of any other embodiment, also described above, without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A method for controlling a pulse width of a square pulse waveform, comprising:
generating the square pulse waveform having a plurality of states, wherein each of the plurality of states includes a series of square pulses; and
modifying the pulse width of each of the plurality of states to modify a rate of processing a substrate.

2. The method of claim 1, wherein the square pulse waveform is not sinusoidal.

3. The method of claim 1, wherein said modifying the pulse width comprises increasing a number of the square pulses to increase a time period of applying the square pulses.

4. The method of claim 3, further comprising maintaining the same duty cycle while the number of square pulses increases.

5. The method of claim 1, wherein the square pulse waveform is supplied via a high frequency filter to a bottom electrode of a plasma chamber, the method further comprising:
generating a sinusoidal continuous waveform;
providing the sinusoidal continuous waveform to an impedance matching circuit coupled to a top electrode of the plasma chamber.

6. The method of claim 5, wherein the impedance matching circuit does not receive a pulsed sinusoidal RF signal while the pulsed width is being modified.

7. The method of claim 1, wherein the series includes a first pulse and a second pulse.

8. The method of claim 1, wherein a time of transition from one of the second plurality of states to one of the first plurality of states facilitates achieving a power setpoint at a first rate faster than a second rate, wherein the second rate is of a transition from a first state of a sinusoidal RF signal to a second state of the sinusoidal RF signal, wherein the power setpoint is achieved faster than achieving the power setpoint by applying the sinusoidal RF signal.

9. The method of claim 1, wherein said modifying the pulse width changes electron temperature and plasma density to modify a chemical composition of plasma.

10. The method of claim 9, wherein said modifying the pulse width includes:
increasing the pulse width to increase a rate of change of the electron temperature and increase a rate of change of the plasma density; or
decreasing the pulse width to decrease the rate of change of electron temperature and decrease the rate of change of plasma density, wherein the decrease in the pulse width increases densities of reactants and reduces density of a fluorinated carbon (CFx), and the increase in the pulse width decreases the densities of reactants and increases the density of fluorinated carbon.

11. The method of claim 1, further comprising:
generating an RF signal pulsing between multiple parameter levels.

12. The method of claim 11, further comprising:
supplying the square pulse waveform to a high frequency (HF) filter, wherein the HF filter is coupled to an impedance matching circuit, wherein the impedance matching circuit is coupled to a substrate support of a plasma chamber;
supplying the RF signal to the impedance matching circuit, wherein the square pulse waveform and the RF signal are supplied when an upper electrode of the plasma chamber is coupled to a ground potential or is floating.

13. A controller for adjusting a pulse width of a square pulse waveform, comprising:
a processor configured to control a pulse generator to generate the square pulse waveform having a plurality of states, wherein each of the plurality of states includes a series of square pulses, wherein the processor is configured to control the pulse generator to modify the pulse width of each of the plurality of states to modify a rate of processing a substrate; and
a memory device coupled to the processor.

14. The controller of claim 13, wherein the square pulse waveform is not sinusoidal.

15. The controller of claim 13, wherein to modify the pulse width, the processor is configured to increase a number of the square pulses to increase a time period of applying the square pulses.

16. The controller of claim 15, wherein the processor is configured to control the pulse generator to maintain the same duty cycle while the number of square pulses increases.

17. The controller of claim 13, wherein the square pulse waveform is supplied via a high frequency filter to a bottom electrode of a plasma chamber, wherein the processor is configured to control an RF signal generator to generate a sinusoidal continuous waveform for providing the sinusoidal continuous waveform to an impedance matching circuit coupled to a top electrode of the plasma chamber.

18. The controller of claim 17, wherein the impedance matching circuit does not receive a pulsed sinusoidal RF signal while the pulsed width is being modified.

19. A plasma system comprising:
a low frequency (LF) radio frequency (RF) pulse generator;
a high frequency (HF) RF signal generator,
an HF filter coupled to the LF RF pulse generator;
an impedance matching circuit coupled to the HF RF signal generator;
a plasma chamber coupled to the HF filter and the impedance matching circuit; and
a controller coupled to the LF RF pulse generator and the HF RF signal generator, wherein the controller is configured to:
control the LF RF pulse generator to generate a square pulse waveform having a plurality of states, wherein each of the plurality of states includes a series of square pulses,
control the LF RF pulse generator to modify a pulse width of each of the plurality of states to modify a rate of processing a substrate.

20. The plasma system of claim 19, wherein the square pulse waveform is not sinusoidal.

21. The plasma system of claim 20, wherein to modify the pulse width, the controller is configured to increase a number of the square pulses to increase a time period of applying the square pulses.

22. The plasma system of claim 21, wherein the controller is configured to control the pulse generator to maintain the same duty cycle while the number of square pulses increases.
